(19) United States
(12) Patent Application Publication
(10) Pub. No.: US 2025/0297065 A1
(43) Pub. Date: Sep. 25, 2025

(54) POLYMER FILM, LAMINATE, AND LAMINATE WITH METAL

(71) Applicant: FUJIFILM Corporation, Tokyo (JP)

(72) Inventors: Yasuyuki SASADA, Kanagawa (JP); Kana MUROI, Kanagawa (JP); Miyoko SHIBANO, Kanagawa (JP)

(73) Assignee: FUJIFILM Corporation, Tokyo (JP)

(21) Appl. No.: 19/230,028

(22) Filed: Jun. 5, 2025

Related U.S. Application Data
(63) Continuation of application No. PCT/JP2023/042082, filed on Nov. 22, 2023.

(30) Foreign Application Priority Data
Dec. 9, 2022 (JP) 2022-197497

(51) Int. Cl. C08G 69/44; B32B 15/08; B32B 15/20; B32B 27/36

(52) U.S. Cl. CPC C08G 69/44; B32B 15/08; B32B 15/20; B32B 27/36; B32B 2250/02; B32B 2311/12; B32B 2367/00

(57) ABSTRACT

A polymer film, in which the polymer film has an elastic modulus at 160° C. of 10 MPa or less, a thermal mass loss rate of 1.0% by mass or less at 290° C., and a dielectric loss tangent of 0.01 or less.

### CROSS-REFERENCE TO RELATED APPLICATIONS

This application is a continuation application of International Application No. PCT/JP2023/042082, filed Nov. 22, 2023, the disclosure of which is incorporated herein by reference in its entirety. Further, this application claims priority from Japanese Patent Application No. 2022-197497, filed Dec. 9, 2022, the disclosure of which is incorporated herein by reference in its entirety.

### BACKGROUND OF THE INVENTION

### 1. Field of the Invention

The present disclosure relates to a polymer film, a laminate, and a laminate with a metal.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, JP2019-199612A discloses an adhesive film including a resin composition containing a styrene-based polymer, an inorganic filler, and a curing agent.

In addition, JP2019-135301A discloses a production method of a thermoplastic liquid crystal polymer film, the production method comprising a preparation step of preparing a thermoplastic liquid crystal polymer film that forms an anisotropic molten phase and has a molecular alignment degree SOR of 0.8 to 1.4, a first degassing step of degassing the thermoplastic liquid crystal polymer film by heating the thermoplastic liquid crystal polymer film in a range of 100° C. to 200° C. for a predetermined time, and a second degassing step of further degassing the thermoplastic liquid crystal polymer film by heating the thermoplastic liquid crystal polymer film in a range of 80° C. to 200° C. for a predetermined time at a degree of vacuum of 1500 Pa or less, in which the thermoplastic liquid crystal polymer film has a molecular alignment degree SOR of 0.8 to 1.4 and a moisture content of 300 ppm or less, and the thermoplastic liquid crystal polymer film is used for a circuit board.

### SUMMARY OF THE INVENTION

Typically, a copper-clad laminated plate is produced by laminating a copper foil on a surface of a polymer film. In addition, the wiring board is produced by superimposing a copper-clad laminated plate and a wiring substrate such that a polymer film in the copper-clad laminated plate and the wiring substrate are in contact with each other. In a case of producing a wiring board, from the viewpoint of adhesiveness, it is required that the polymer film deforms by following the step formed on the surface of the wiring substrate.

On the other hand, in a case where a polymer film having excellent step followability with respect to the wiring substrate is used for the copper-clad laminated plate, interlayer peeling may occur in a reflow soldering step performed in a case of mounting an electronic component. Therefore, it has been required to achieve both excellent step followability with respect to the wiring substrate and excellent adhesiveness during reflow soldering (that is, excellent heat resistance).

An object to be achieved by an embodiment of the present disclosure is to provide a polymer film having excellent step followability and excellent heat resistance.

In addition, an object to be achieved by another embodiment of the present disclosure is to provide a laminate and a laminate with a metal, which have excellent step followability and heat resistance.

The means for achieving the above-described objects include the following aspects.
<1> A polymer film,
in which the polymer film has
   an elastic modulus at 160° C. of 10 MPa or less,
   a thermal mass loss rate at 290° C. of 1.0% by mass or less, and
   a dielectric loss tangent of 0.01 or less.
<2 The polymer film according to <1>, in which the polymer film has an elastic modulus at 290° C. is 0.01 MPa or more.
<3> The polymer film according to <1> or <2>, further including an antioxidant.
<4> The polymer film according to <3>, in which the antioxidant is a radical scavenger.
<5> The polymer film according to any one of <1> to <4>, in which the polymer film does not contain a metal atom, or a content of a metal atom is less than 0.1% by mass with respect to a total amount of the polymer film.
<6> The polymer film according to any one of <1> to <5> further includes a polymer, in which the polymer contains a liquid crystal polymer.
<7> The polymer film according to <6>, in which the polymer contains an aromatic polyester amide.
<8> The polymer film according to any one of <1> to <7>, in which a thermoplastic resin containing a constitutional unit based on a monomer having an aromatic hydrocarbon group.
<9> A laminate including:
a layer A; and
a layer B provided on at least one surface of the layer A,
in which the layer B has an elastic modulus at 160° C. of 10 MPa or less, and
the laminate has a thermal mass loss rate at 290° C. of 1.0% by mass or less and a dielectric loss tangent of 0.01 or less.
<10> The laminate according to <9>, in which a ratio of an average thickness of the layer B to an average thickness of the laminate is 0.3 or more.
<11> The laminate according to <9> or <10>, in which the laminate has an elastic modulus at 290° C. of 0.01 MPa or more.
<12> The laminate according to any one of <9> to <11>, further including an antioxidant.
<13> The laminate according to <12>, in which the antioxidant is a radical scavenger.
<14> The laminate according to any one of <9> to <13>, further including:
a layer C,
in which the layer B, the layer A, and the layer C are provided in this order.
<15> The laminate according to any one of <9> to <14>, in which the laminate does not contain a metal atom, or a content of a metal atom is less than 0.1% by mass with respect to a total amount of the laminate.
<16> A laminate with a metal including the polymer film according to any one of <1> to <8> or the laminate according to any one of <9> to <15>, and a metal layer or a metal wire disposed on at least one surface of the polymer film or the laminate.

According to one embodiment of the present disclosure, it is possible to provide a polymer film having excellent step followability and excellent heat resistance.

In addition, according to another embodiment of the present disclosure, it is possible to provide a laminate and a laminate with a metal which have excellent step followability and excellent heat resistance.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights in terms of polystyrene used as a standard substance, which are detected by using a solvent tetrahydrofuran (THF), a differential refractometer, and a gel permeation chromatography (GPC) analyzer using TSKgel GMHxL, TSKgel G4000HxL, and TSKgel G2000HxL (all trade names manufactured by Tosoh Corporation) as columns, unless otherwise specified.

In the present disclosure, the “polymer” is a compound having a weight-average molecular weight of 3,000 or more and a glass transition temperature higher than 25° C.

In the present disclosure, the “elastomer” is a compound having a weight-average molecular weight of 3,000 or more and a glass transition temperature of 25° C. or lower.

In the present disclosure, the glass transition temperature is measured by differential scanning calorimetry (DSC). For example, the measurement can be performed using a product name “DSC-60A Plus” (manufactured by Shimadzu Corporation) or the like. A temperature rising rate in the measurement is set to 10° C./minute.

### [Polymer Film]

The polymer film according to the present disclosure has an elastic modulus at 160° C. of 10 MPa or less, a thermal mass loss rate at 290° C. of 1.0% by mass or less, and a dielectric loss tangent of 0.01 or less.

As a result of intensive studies, the inventors of the present invention have found that a polymer film having excellent step followability and excellent heat resistance can be provided by adopting the above-described configuration.

The detailed mechanism that brings about the aforementioned effect is unclear, but is assumed to be as below.

In the polymer film according to the present disclosure, the elastic modulus of layer B at 160° C. is 10 MPa or less. Therefore, it is presumed that during lamination and pressing with the wiring pattern, the deformation of layer B due to pressing pressure is greater than that of other layers that are harder than layer B, thereby improving step followability.

In addition, in the polymer film according to the present disclosure, since the thermal mass loss rate at 290° C. is 1.0% by mass or less, thermal decomposition of the constituent material is suppressed in a high temperature environment, and generation of outgas is suppressed, so that interlayer peeling is less likely to occur. That is, the heat resistance is excellent.

From the viewpoint of step followability, the elastic modulus of the polymer film at 160° C. is preferably 0.1 MPa to 8 MPa, more preferably 0.3 MPa to 5 MPa, and still more preferably 0.3 MPa to 4 MPa.

In the present disclosure, the elastic modulus of the polymer film at 160° C. is measured by the following method.

First, a film cross-section sample (length: 2 mm× width: 2 mm) produced by cutting a surface of a polymer film with a microtome is prepared.

Next, an elastic modulus of the film cross-section sample at 160° C. is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

In a case where the laminate includes a support such as a metal layer, the elastic modulus of the layer B at 160° C. included in the laminate described below is measured by preparing a film cross-section sample (length: 2 mm× width: 2 mm) produced by cutting a surface of the layer B with a microtome after etching the laminate.

From the viewpoint of heat resistance, the elastic modulus of the polymer film at 290° C. is preferably 0.01 MPa or more, more preferably 0.02 MPa to 0.10 MPa, and still more preferably 0.03 MPa to 0.08 MPa.

In the present disclosure, the elastic modulus of the polymer film at 290° C. is measured by the following method.

First, a film cross-section sample (length: 2 mm× width: 2 mm) produced by cutting a surface of a polymer film with a microtome is prepared.

Next, an elastic modulus of the film cross-section sample at 290° C. is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

In a case where the laminate includes a support such as a metal layer, the elastic modulus of the layer B at 290° C. included in the laminate described below is measured by preparing a film cross-section sample (length: 2 mm× width: 2 mm) produced by cutting a surface of the layer B with a microtome after etching the laminate.

The dielectric loss tangent of the polymer film is preferably 0.005 or less, and more preferably more than 0 and 0.003 or less.

In the present disclosure, the dielectric loss tangent is measured by the following method.

The dielectric loss tangent is measured by a resonance perturbation method at a frequency of 10 GHz. A 10 GHz cavity resonator (for example, “CP531” manufactured by Kanto Electronic Application & Development Inc.) is connected to a network analyzer (for example, “E8363B” manufactured by Agilent Technology Company), a polymer film is inserted into the cavity resonator, and the measurement is performed from the change in resonance frequency before and after the insertion for 96 hours in an environment of a temperature of 25° C. and a humidity of 60% RH.

The dielectric loss tangent of the laminate described below is measured by inserting the laminate instead of the polymer film.

The thermal mass loss rate of the polymer film at 290° C. is preferably 0.8% by mass or less, more preferably 0.5% by mass or less, still more preferably 0.3% by mass or less, particularly preferably 0.2% by mass or less, and may be 0% by mass.

The thermal mass loss rate can be adjusted by changing the material constituting the polymer film. For example, the thermal mass loss rate can be reduced by increasing the content of the polymer and reducing the content of the elastomer. In addition, by increasing the molecular weight of the elastomer, the thermal mass loss rate can be reduced.

In the present disclosure, the thermal mass loss rate at 290° C. is measured by the following method.

The polymer film is heated from 25° C. to 290° C. (temperature rising rate: 50° C./min) in a nitrogen environment and held for 40 minutes.

The mass of the polymer film after 35 minutes from the start of the holding and the mass of the polymer film after 25 minutes from the start of the holding are substituted into the following expression to obtain the thermal mass loss rate.

Thermal mass loss rate (%)=(mass of polymer film after 25 minutes from start of holding−mass of polymer film after 35 minutes from start of holding)/mass of polymer film after 25 minutes from start of holding×100

In a case where the thermal mass loss rate of the layer B included in the laminate including the metal layer described later is measured, the metal foil is removed by a known wet etching method using an aqueous solution of ferric chloride or the like, washed with pure water, and dried, and then the above measurement is performed on the laminate.

From the viewpoint of dielectric loss tangent, heat resistance, and step followability, the average thickness of the polymer film is preferably 5 μm to 90 μm, more preferably 10 μm to 70 μm, and still more preferably 15 μm to 50 μm.

In the present disclosure, a measuring method of the average thickness is as follows.

The polymer film is cut along a plane perpendicular to a plane direction of the polymer film, thicknesses are measured at five or more points on a cross section thereof, and an average value thereof is defined as the average thickness.

The average thickness of each layer in the laminate described later is obtained by cutting the laminate along a plane perpendicular to a plane direction of the laminate, by measuring the thickness of five or more points in the cross section of each layer, and by calculating the average value of the measured values.

From the viewpoint of heat resistance and step followability, the polymer film according to the present disclosure preferably has a phase-separated structure including at least two phases.

In the present disclosure, the “phase-separated structure” means a structure in which at least two portions containing components different from each other are present in the polymer film or the layer.

Examples of the phase-separated structure include a sea-island structure, a co-continuous structure, a cylinder structure, and a lamella structure. The sea-island structure means a structure in which one phase of the at least two phases forms a continuous phase and the other phase is dispersed in a discontinuous manner. In addition, the co-continuous structure means a structure in which all of the at least two phases form a continuous phase. The cylinder structure means a structure having, in at least one phase of the at least two phases, a plurality of rod-like phases which are other phases. The lamella structure means a layered structure in which the at least two phases are alternately overlapped. Both the cylinder structure and the lamella structure are structures in which all of the at least two phases form a continuous phase, but they are distinguished from the co-continuous structure in that they have the above-described characteristics (rod-like or layered).

It is preferable that the polymer film according to the present disclosure has a phase-separated structure in which all of the at least two phases form a continuous phase. Specifically, the phase-separated structure in the polymer film according to the present disclosure is preferably the co-continuous structure, the cylinder structure, or the lamella structure.

The fact that the film has a phase-separated structure can be confirmed by a method of observing a morphology, evaluating a material distribution, evaluating a mechanical property distribution, or the like for the film surface, the film cross section, or both the film surface and the film cross section. The morphological observation can be performed using a known optical microscope, an electron microscope, or the like. The material distribution evaluation can be performed using imaging such as infrared spectroscopy, Raman spectroscopy, and an X-ray photoelectron spectroscopy apparatus. The evaluation of the mechanical property distribution can be performed using an atomic force microscope.

In one embodiment, whether or not the polymer film has a phase-separated structure can be confirmed by performing differential scanning calorimetry (DSC) on the entire surface. Specifically, in a case where the glass transition temperature (Tg) derived from the polymer and the transition temperature (for example, Tg) derived from a component different from the polymer are detected, it can be determined that phase separation occurs.

The phase-separated structure can be formed of a polymer, an elastomer, or the like described later.

From the viewpoint of heat resistance, the glass transition temperature (Tg) of the polymer film according to the present disclosure is preferably 120° C. or higher, more preferably 140° C. or higher, and still more preferably 160° C. or higher.

In the present disclosure, the Tg of the polymer film is measured as follows.

A 5 mg of the polymer film was placed in a measurement pan of a differential scanning calorimeter (DSC) under conditions of 25° C. and a relative humidity of 10%, the temperature was raised from −150° C. to 200° C. at 10° C./min in a nitrogen stream, and a temperature at which a baseline began to be biased from a low temperature side was defined as Tg.

The Tg of the layer B in the laminate described later is measured by scraping off the layer B with a razor and taking out the layer B.

### —Polymer—

The polymer film of the present disclosure can contain a polymer. Examples of the polymer include thermoplastic resins such as a liquid crystal polymer, a fluororesin, a polymerized substance of a compound having a cyclic aliphatic hydrocarbon group and a group having an ethylenically unsaturated bond, a polyether ether ketone, a polyolefin, a polyamide, a polyester, a polyphenylene sulfide, a polyether ketone, a polycarbonate, a polyether sulfone, a polyphenylene ether and a modified product thereof, and a polyether imide; and thermosetting resins such as a phenol resin, an epoxy resin, a polyimide, and a cyanate resin.

Among the above, from the viewpoint of reducing the dielectric loss tangent, the polymer preferably includes a liquid crystal polymer.

### —Liquid Crystal Polymer—

The kind of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of kinds of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably equal to or higher than 250° C., more preferably 250° C. to 350° C., and still more preferably 260° C. to 330° C.

In the present disclosure, the melting point is measured using a differential scanning calorimetry apparatus. For example, the measurement is performed using product name “DSC-60A Plus” (manufactured by Shimadzu Corporation). A temperature rising rate in the measurement is set to 10° C./minute.

A weight-average molecular weight of the liquid crystal polymer is preferably 1,000,000 or less, more preferably 3,000 to 300,000, still more preferably 5,000 to 100,000, and particularly preferably 5,000 to 30,000.

The liquid crystal polymer preferably contains an aromatic polyester amide from a viewpoint of further decreasing the dielectric loss tangent. The aromatic polyester amide is a resin having at least one aromatic ring and having an ester bond and an amide bond. Among these, from the viewpoint of heat resistance, the aromatic polyester amide is preferably a fully aromatic polyester amide.

The aromatic polyester amide is preferably a crystalline polymer. The polymer film according to the present disclosure preferably contains a crystalline aromatic polyester amide. Aromatic polyester amide included in the film is crystalline, whereby the dielectric loss tangent further decreases.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature rising rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a constitutional unit represented by Formula 1, a constitutional unit represented by Formula 2, and a constitutional unit represented by Formula 3.

—O-Ar1-CO— Formula 1

—CO-Ar2-CO— Formula 2

—NH-Ar3-O— Formula 3

In Formula 1 to Formula 3, Ar1, Ar2, and Ar3 each independently represent a phenylene group, a naphthylene group, or a biphenylylene group.

Hereinafter, the constitutional unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar1 is preferably a p-phenylene group, a 2,6-naphthylene group, or a 4,4′-biphenylylene group, and more preferably a 2,6-naphthylene group.

In a case where Ar1 is a p-phenylene group, the unit 1 is, for example, a constitutional unit derived from p-hydroxybenzoic acid.

In a case where Ar1 is a 2,6-naphthylene group, the unit 1 is, for example, a constitutional unit derived from 6-hydroxy-2-naphthoic acid.

In a case where Ar1 is a 4,4′-biphenylylene group, the unit 1 is, for example, a constitutional unit derived from 4′-hydroxy-4-biphenylcarboxylic acid.

In Formula 2, Ar2 is preferably a p-phenylene group, an m-phenylene group, or a 2,6-naphthylene group, and more preferably an m-phenylene group.

In a case where Ar2 is a p-phenylene group, the unit 2 is, for example, a constitutional unit derived from terephthalic acid.

In a case where Ar2 is an m-phenylene group, the unit 2 is, for example, a constitutional unit derived from isophthalic acid.

In a case where Ar2 is a 2,6-naphthylene group, the unit 2 is, for example, a constitutional unit derived from 2,6-naphthalenedicarboxylic acid.

In Formula 3, Ar3 is preferably a p-phenylene group or a 4,4′-biphenylylene group, and more preferably a p-phenylene group.

In a case where Ar3 is a p-phenylene group, the unit 2 is, for example, a constitutional unit derived from p-aminophenol.

In a case where Ar3 is a 4,4′-biphenylylene group, the unit 2 is, for example, a constitutional unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the constitutional units is a value obtained by totaling a substance amount (mol) of each constitutional unit. The substance amount of each constitutional unit is calculated by dividing a mass of each constitutional unit constituting aromatic polyester amide by a formula weight of each constitutional unit.

In a case where a ratio of the content of the unit 2 to the content of the unit 3 is expressed as [Content of unit 2]/[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other constitutional units other than the unit 1 to the unit 3. A content of other constitutional units is preferably 10% by mole or less and more preferably 5% by mole or less with respect to the total content of all constitutional units.

Aromatic polyester amide is preferably produced by subjecting a source monomer corresponding to the constitutional unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### ——Fluororesin——

From the viewpoint of heat resistance and mechanical strength, the polymer may contain a fluororesin.

In the present disclosure, the kind of the fluororesin is not particularly limited, and a known fluororesin can be used.

Examples of the fluororesin include a homopolymer and a copolymer containing a constitutional unit derived from a fluorinated α-olefin monomer, that is, an α-olefin monomer containing at least one fluorine atom. In addition, examples of the fluororesin include a copolymer containing a constitutional unit derived from a fluorinated α-olefin monomer, and a constitutional unit derived from a non-fluorinated ethylenically unsaturated monomer reactive to the fluorinated α-olefin monomer.

Examples of the fluorinated α-olefin monomer include CF₂=CF₂, CHF=CF₂, CH₂—CF₂, CHCl=CHF, CClF=CF₂, CCl₂—CF₂, CClF=CClF, CHF=CCl₂, CH₂=CClF, CCl₂=CClF, CF₃CF=CF₂, CF₃CF=CHF, CF₃CH—CF₂, CF₃CH—CH₂, CHF₂CH═CHF, CF₃CF=CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂—CF₂), chlorotrifluoroethylene (CClF=CF₂), (perfluorobutyl)ethylene, vinylidene fluoride (CH₂=CF₂), and hexafluoropropylene (CF₂—CFCF3) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), (ECTFE), poly(hexafluoropropylene), poly(ethylene-chlorotrifluoroethylene) poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a constitutional unit derived from fluorinated ethylene or fluorinated propylene.

The fluororesin may be used alone or in combination of two or more thereof.

The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a constitutional unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by Formula: H₂C—CR′COO—(CH₂)ₙ—R—(CH₂)ₙ—OOCR′═CH₂.

In the formula, R is an oligomer chain having a constitutional unit derived from the fluorinated α-olefin monomer, R′ is H or —CH₃, and n is 1 to 4. R may be a fluorine-based oligomer chain having a constitutional unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

——Polymerized Substance of Compound which has Cyclic Aliphatic Hydrocarbon Group and Group Having Ethylenically Unsaturated Bond——

The polymer may include a polymerized substance of a compound having a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a constitutional unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### —Polyphenylene Ether—

The polymer may contain a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

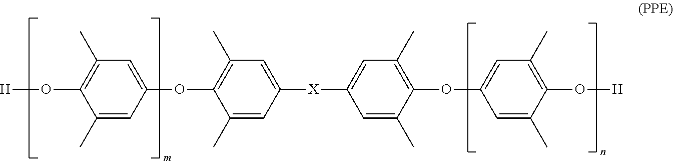

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and more preferably 500 to 3,000. In addition, in a case where the heat curing is not performed, the weight-average molecular weight (Mw) of the polyphenylene ether is not particularly limited, but is preferably 3,000 to 100,000 and more preferably 5,000 to 50,000.

### —Aromatic Polyether Ketone—

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

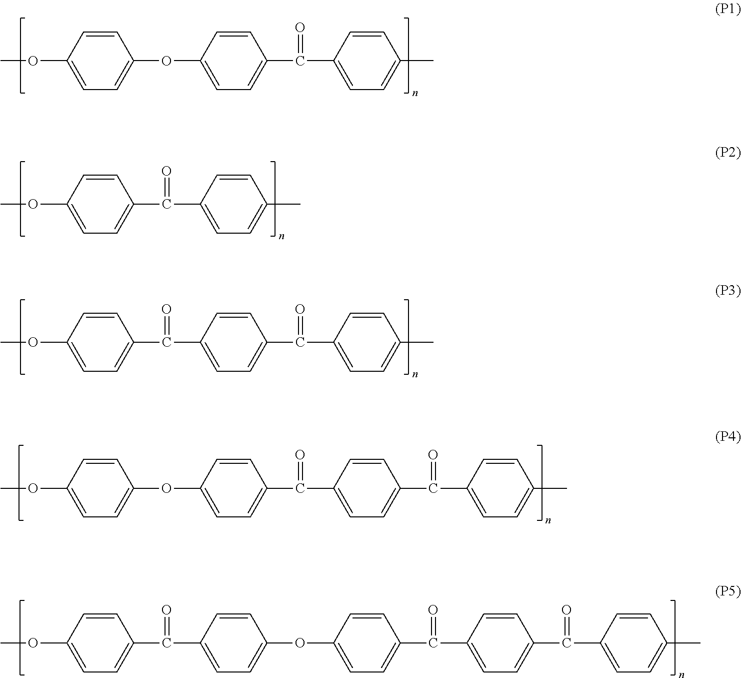

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

From the viewpoint of dielectric loss tangent of the polymer film, a content of the polymer with respect to the total mass of the polymer film is preferably 10% by mass or more, more preferably 13% by mass or more, still more preferably 15% by mass to 60% by mass, and particularly preferably 18% by mass to 40% by mass.

In a case where the polymer includes a liquid crystal polymer (preferably an aromatic polyester amide), from the viewpoint of reducing the dielectric loss tangent, the content of the liquid crystal polymer with respect to the total mass of the polymer is preferably 50% by mass or more, more preferably 70% by mass or more, still more preferably 90% by mass or more, and may be 100% by mass.

—Thermoplastic Resin Containing Constitutional Unit Derived from Monomer Having Aromatic Hydrocarbon Group—

From the viewpoint of dielectric loss tangent, heat resistance, and step followability, the polymer film preferably contains a thermoplastic resin containing a constitutional unit derived from a monomer having an aromatic hydrocarbon group, and more preferably contains a polystyrene-based elastomer.

Examples of the styrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

From the viewpoint of suppressing thermal decomposition and improving heat resistance, the weight-average molecular weight of the thermoplastic resin including a constitutional unit derived from a monomer having an aromatic hydrocarbon group is preferably 10,000 to 500,000, more preferably 30,000 to 300,000, and still more preferably 50,000 to 200,000.

In a case where the molecular weight has a distribution, the molecular weight represents a weight-average molecular weight (Mw). Mw is measured by gel permeation chromatography (GPC) using tetrahydrofuran (THF) as an eluent, in terms of polystyrene.

From the viewpoint of dielectric loss tangent, heat resistance, and step followability, the content of the above-described thermoplastic resin with respect to the total mass of the polymer film is preferably 40% by mass to 85% by mass, more preferably 40% by mass to 80% by mass, and still more preferably 60% by mass to 80% by mass.

### —Antioxidant—

From the viewpoint of heat resistance, the polymer film preferably includes an antioxidant. The polymer film may contain two or more kinds of antioxidants.

The kind of the antioxidant is not particularly limited, but from the viewpoint of suppressing thermal decomposition of the material constituting the polymer film and improving heat resistance, a radical scavenger is preferable.

Examples of the radical scavenger include a phenol-based radical scavenger, a hindered amine-based radical scavenger, a hydroquinone-based radical scavenger, a phenothiazine-based radical scavenger, a nitroso-based radical scavenger, and an N-oxyl-based radical scavenger.

Among the above, from the viewpoint of heat resistance, a phenol-based radical scavenger or a hindered amine-based radical scavenger is preferable, and a hindered phenol-based antioxidant, a semi-hindered phenol-based antioxidant, or a hindered amine-based radical scavenger is more preferable.

As the antioxidant, for example, various antioxidants described in “Handbook of Antioxidants” published by Taiseisha Ltd. (first edition published on Oct. 25, 1976), “Handbook of Polymer Additives” published by CMC Publishing Co., Ltd. (edited by Tetsu Haruna, first edition published on Nov. 7, 2010), and the like can be used.

In addition, the antioxidant may be a primary antioxidant such as a hindered phenol-based antioxidant, an amine-based antioxidant, a lactone-based antioxidant, or a hydroxylamine-based antioxidant, or may be a secondary antioxidant such as a sulfur-based oxidant or a phosphorus-based oxidant.

Examples of the hindered phenol-based antioxidant include 2,6-di-tert-butyl-4-methylphenol, 2,6-di-tert-butyl-4-ethylphenol, mono (or di or tri)(α-methylbenzyl) phenol, 2,2′-methylenebis(4-ethyl-6-tert-butylphenol), 2,2′-methylenebis(4-methyl-6-tert-butylphenol), 4,4′-butylidenebis(3-methyl-6-tert-butylphenol), 4,4′-thiobis(3-methyl-6-tert-butylphenol), 2,5-di-tert-butylhydroquinone, 2,5-di-tert-amylhydroquinone, triethylene glycol-bis-[3-(3-t-butyl-5-methyl-4-hydroxyphenyl) propionate], 1,6-hexanediol-bis [3-(3,5-di-t-butyl-4-hydroxyphenyl) propionate], 2,4-bis-(n-octylthio)-6-(4-hydroxy-3,5-di-t-butylanilino)-1,3,5-triazine, pentaerythritol-tetrakis [3-(3,5-di-t-butyl-4-hydroxyphenyl) propionate], 2,2-thiodiethylene bis [3-(3,5-di-t-butyl-4-hydroxyphenyl) propionate], octadecyl-3-(3,5-di-t-butyl-4-hydroxyphenyl) propionate, N,N′-hexamethylenebis(3,5-di-t-butyl-4-hydroxy-hydrocinnamide), 3,5-di-t-butyl-4-hydroxy-benzylphosphonate-diethyl ester, 1,3,5-trimethyl-2,4,6-tris(3,5-di-t-butyl-4-hydroxybenzyl)benzene, bis(3,5-di-t-butyl-4-hydroxybenzylphosphonic acid ethyl) calcium, tris-(3,5-di-t-butyl-4-hydroxybenzyl) isocyanurate, 2,4-2,4-bis [(octylthio)methyl] o-cresol, N,N′-bis [3-(3,5-di-t-butyl-4-hydroxyphenyl) propionyl] hydrazine, tris(2,4-di-t-butylphenyl)phosphate, 2-(5-methyl-2-hydroxyphenyl)benzotriazole, 2-[2-hydroxy-3,5-bis(α,α-dimethylbenzyl)phenyl]-2H-benzotriazole, 2-(3,5-di-t-butyl-2-hydroxyphenyl)benzotriazole, 2-(3-t-butyl-5-methyl-2-hydroxyphenyl)-5-chlorobenzotriazole, 2-(3,5-di-t-butyl-2-hydroxyphenyl)-5-chlorobenzotriazole, 2-(3,5-di-t-amyl-2-hydroxyphenyl)benzotriazole, 2-(2′-hydroxy-5′-t-octylphenyl)-benzotriazole, a condensate with methyl-3-[3-t-butyl-5-(2H-benzotriazole-2-yl)-4-hydroxyphenyl]propionate-polyethylene glycol (molecular weight: about 300), a hydroxyphenylbenzotriazole derivative, 2-(3,5-di-t-butyl-4-hydroxybenzyl)-2-n-butylmalonic acid bis(1,2,2,6,6-pentamethyl-4-piperidyl), and 2,4-di-t-butylphenyl-3,5-di-t-butyl-4-hydroxybenzoate.

Examples of the commercially available hindered phenol-based antioxidants include NOCLAC 200, NOCLAC M-17, NOCLAC SP, NOCLAC SP-N, NOCLAC NS-5, NOCLAC NS-6, NOCLAC NS-30, NOCLAC 300, NOCLAC NS-7, and NOCLAC DAH (all of which are manufactured by Ouchi Shinko Chemical Industry Co., Ltd.), MARK AO-30, MARK AO-40, MARK AO-50, MARK AO-60, MARK AO-616, MARK AO-635, MARK AO-658, MARK AO-80, MARK AO-15, MARK AO-18, MARK 328, and MARK AO-37 (all of which are manufactured by ADEKA Corporation), IRGANOX 245, IRGANOX 259, IRGANOX 565, IRGANOX 1010, IRGANOX 1024, IRGANOX 1035, IRGANOX 1076, IRGANOX 1081, IRGANOX 1098, IRGANOX 1222, IRGANOX 1330, and IRGANOX 1425WL (all of which are manufactured by BASF Japan Ltd.), SUMILIZER GM and SUMILIZER GA-80 (both of which are manufactured by Sumitomo Chemical Co., Ltd.), and SONGNOX 1010, SONGNOX 1076, SONGNOX 1077, SONGNOX 1135, SONGNOX 2450, SONGNOX 3114, SONGNOX 1035, SONGNOX 1024, SONGNOX 1290, SONGNOX 2590, SONGNOX 1098, SONGNOX 4150, SONGNOX 4425, SONGNOX 2246, SONGNOX 2500, SONGNOX 1330, SONGNOX 1790, and SONGNOX 1520 (all of which are manufactured by SONGWON Industrial Co., Ltd.).

The amine-based antioxidant is not particularly limited, and conventionally known antioxidants can be widely used. Specific examples thereof include, as the amine-ketone-based compound, a 2,2,4-trimethyl-1,2-dihydroquinoline polymer, 6-ethoxy-1,2-dihydro-2,2,4-trimethylquinoline, a reactant of diphenylamine and acetone, and the like. Specifically, examples of the product name include, but are not limited to, NOCRAC 224, NOCRAC AW, NOCRAC AW-N, NOCRAC B, and NOCRAC B-N (all of which are manufactured by Ouchi Shinko Chemical Industrial Co., Ltd.), ANTAGE RD, ANTAGE RD-G, and ANTAGE AW (all of which are manufactured by Kawaguchi Chemical Industry Co., Ltd.), NONFLEX RD, NONFLEX QS, NONFLEX AW, NONFLEX BA, NONFLEX BA-P, and NONFLEX BAR (all of which are manufactured by Seiko Chemical Co., Ltd.), BUKANOX HS/LG and BUKANOX HS/powder (all of which are manufactured by Bayer AG), KORESTAB TMQ (manufactured by S&S Japan Co., Ltd.), and AMINOX (manufactured by Shiraishi Calcium Kaisha, Ltd.).

Examples of the aromatic amine compound include a naphthylamine-based antioxidant, a diphenylamine-based antioxidant, and a p-phenylenediamine-based antioxidant. Specific examples of these compounds are not particularly limited, but include a naphthylamine-based antioxidant such as phenyl-α-naphthylamine; a diphenylamine-based antioxidant such as p-(p-toluenesulfonylamide)diphenylamine, 4,4′-bis(α,α-dimethylbenzyl)diphenylamine, 4,4′-distyryldiphenylamine, 4,4′-dioctyldiphenylamine, octylated diphenylamine, a reactant of diphenylamine and diisobutylene, alkylated diphenylamine, p-isopropoxy-diphenylamine, bis(phenyl-isopropylidene)-4,4-diphenylamine, 4-(α-phenylethyl)diphenylamine, 4,4′-bis(α-phenylethyl)diphenylamine, styrenated diphenylamine, di-tert-butyldiphenylamine, and a diphenylamine derivative; and a p-phenylenediamine-based antioxidant such as N,N′-diphenyl-p-phenylenediamine, N-isopropyl-N′-phenyl-p-phenylenediamine, N,N′-di-2-naphthyl-p-phenylenediamine, N-phenyl-N′-(3-methacryloyloxy-2-hydroxypropyl)-p-phenylenediamine, 4-(anilinophenyl) methacrylamide, 4-(mercaptoacetamide)diphenylamine, 2-[(mercaptoacetoxy)oxy]ethyl-3-[4-(phenylamino)phenyl]amino butanate, N,N′-bis(1-methylheptyl)-p-phenylenediamine, N,N-bis(1,4-dimethylpentyl)-p-phenylenediamine, N-(1,3-dimethylbutyl)-N′-phenyl-p-phenylenediamine, N-cyclohexyl-N′-phenyl-p-phenylenediamine, 2,4,6-tris(N-1,4-dimethylpentyl-p-phenylenediamino)-1,3,5-triazine, a diallyl-p-phenylenediamine mixture, and phenyl-octyl-p-phenylenediamine. Specific examples of the product name include, but are not limited to, NOCRAC PA, NOCRAC ODA, NOCRAC ODA-N, NOCRAC AD-F, NOCRAC CD, NOCRAC TD, NOCRAC White, NOCRAC DP, NOCRAC 810-NA, NOCRAC 6C, NOCRAC G-1, and NOCRAC 500 (all of which are manufactured by Ouchi Shinko Chemical Industrial Co., Ltd.), ANTAGE OD, ANTAGE LDA, ANTAGE DDA, ANTAGE 3C, ANTAGE 6C, ANTAGE STDP-N, and ANTAGE BC (all of which are manufactured by Kawaguchi Chemical Industry Co., Ltd.), NONFLEX OD-R, NONFLEX BA, NONFLEX BAR, NONFLEX OD-3, NONFLEX DCD, NONFLEX H, NONFLEX F, NONFLEX 3CH, NONFLEX LAS-P, STEARLER LAS, STEARLER STAR, OZONON 3C, OZONON 6C, OZONON 35, OZONON 35-PR, and OZONON 3 W (all of which are manufactured by Seiko Chemical Co., Ltd.), BIRKANOX OCD/SG, BIRKANOX 4010NA, BIRKANOX 4030, BIRKANOX 4020/LG, BIRKANOX 3100, and RENOGRAN IPPD (all of which are manufactured by Bayer AG), NOWGUARD PANA, ALANOX, and NOWGUARD 445 (all of which are manufactured by Chemsture Co., Ltd.), IRGANOX 5057 and IRGAZONE 997 (manufactured by BASF Japan Ltd.), WINGSTAY 29 (manufactured by U.S. Trade), SUMILIZER 9A and ANTIGEN 3C (all of which are manufactured by Sumitomo Chemical Co., Ltd.), PERMANOX IPPD, SANTOFLEX 44, and SANTOFLEX 6PPD (manufactured by Flexsys).

Specific examples of the lactone-based antioxidant and the hydroxylamine-based antioxidant include commercially available products such as 5,7-di-t-butyl-3-(3,4-dimethylphenyl)-3H-benzofuran-2-one (IRGANOX HP-136, manufactured by BASF Japan Ltd.), IRGASTAB FS 042 and a blend containing IRGASTAB FS 042 (manufactured by BASF Japan Ltd.), and GENOX EP (manufactured by Crompton Corporation).

The sulfur-based oxidant is not particularly limited, and conventionally known sulfur-based oxidants can be widely used. Specific examples thereof include 4,4′-thiobis(3-methyl-6-tert-butylphenol), dilauryl-thiodipropionate, bis {2-methyl-4-[3-n-alkyl (C12 or C14)thiopropionyloxy]-5-tert-butylphenyl}sulfide, pentaerythrityl-tetrakis(3-lauryl thiopropionate), ditridecyl-3,3′-thiodipropionate, distearyl-thiodipropionate, 2,2-thio-diethylene bis [3-(3,5-di-t-butyl-4-hydroxyphenyl) propionate], 4,6-bis [(octylthio)methyl]o-cresol, 2,4-bis-(n-octylthio)-6-(4-hydroxy-3,5-di-t-butylanilino)-1,3,5-triazine, dimyristyl-3,3′-thiodipropionate, dibutylmethylene-bis-thioglucoate, and the like. In terms of product name, examples thereof include NOCRAC 300 and NOCRAC 400 (both manufactured by Ouchi Shinko Chemical Industrial Co., Ltd.), ADEKA STAB AO-23, AO-412S, and AO-503A (all manufactured by ADEKA Corporation), IRGANOX-PS800FL, IRGANOX-PS802FL, IRGANOX-1035, IRGANOX-1520L, and IRGANOX-565 (all manufactured by BASF Japan Ltd.), SMILIZER TPL-R, SMILIZER TPS, SMILIZER TPM, SMILIZER WX-R, and SMILIZER TP-D (all manufactured by Sumitomo Chemical Industry Co., Ltd.), CINOX BCS (manufactured by Shipro Kasei Kaisha, Ltd.), BUKANOL 88 (manufactured by Bayer AG), SONGNOX 4120, SONGNOX DLTDP, SONGNOX DMTDP, SONGNOX DSTDP, and SONGNOX DTDT (all manufactured by SONGWON Industrial Co., Ltd.), and the like.

The phosphorus-based oxidant is not particularly limited, and known oxidants in the related art can be widely used. However, since phosphoric acid and phosphoric acid ester containing active hydrogen affect the storage stability of the composition and the heat resistance of the cured product, an alkyl phosphite, an aryl phosphite, an alkyl aryl phosphite compound, or the like, which does not contain phosphoric acid and phosphoric acid ester in the molecule, is preferable. Specific examples of such a phosphorus-based antioxidant include tris(nonylphenyl) phosphite, tris(mono, dinonylphenyl) phosphite, diphenyl, mono(2-ethylhexyl)phosphite, diphenyl, mono(tridecyl) phosphite, diphenyl, mono(isodecyl) phosphite, diphenyl, mono(isooctyl) phosphite, diphenyl, mono(nonylphenyl) phosphite, triphenylphosphite, tris(tridecyl) phosphite, trioisodecylphosphite, tris(2-ethylhexyl)phosphite, trilaurylphosphite, trioleylphosphite, tristearylphosphite, tris(2,4-di-t-butylphenyl)phosphite, tetraphenyldipropylene glycolide phosphite, tetraphenyl tetra(tridecyl) pentaerythritol tetraphosphite, 1,1,3-tris(2-methyl-4-di-tridecylphosphite-5-t-butylphenyl) butane, 4,4′-butylidenebis(3-methyl-6-t-butyl-di-tridecylphosphite), 2,2′-methylene bis(4,6-di-t-butylphenol) octylphosphite, 4,4′-isopropylidene-diphenol alkyl (C12 to C15)phosphite, cyclic neopentane tetrayl bis(2,4-di-t-butylphenylphosphite), cyclic neopentane tetrayl bis(2,6-di-t-butyl-4-methylphenylphosphite), cyclic neopentane tetrayl bis(nonylphenylphosphite), bis(nonylphenyl) pentaerythritol diphosphite, distearyl, pentaerythritol, diphosphite, bis [2,4-bis(1,1′-dimethylethyl)-6-methylphenyl]ethyl ester phosphite, and the like.

From the viewpoint of heat resistance, the content of the antioxidant with respect to the total mass of the polymer film is preferably 0.01% by mass to 10% by mass, more preferably 0.02% by mass to 7% by mass, still more preferably 0.04% by mass to 5% by mass, and particularly preferably 0.04% by mass to 3% by mass.

### —Curing Agent—

From the viewpoint of dielectric loss tangent, heat resistance, and step followability, the polymer film preferably contains at least one of a curing agent or a cured product of the thermoplastic resin and the curing agent.

The curing agent preferably has at least one of an epoxy group or a maleimide group.

From the viewpoint of dielectric loss tangent, heat resistance, and step followability, the content of the curing agent with respect to the total mass of the polymer film is preferably 1% by mass to 20% by mass, more preferably 3% by mass to 15% by mass, and still more preferably 5% by mass to 13% by mass.

### —Filler—

From the viewpoint of dielectric loss tangent, heat resistance, and step followability, the polymer film preferably contains a filler.

The filler may be particulate or fibrous. In addition, the filler may be an inorganic filler or an organic filler. From the viewpoint of dielectric loss tangent, heat resistance, and step followability of the polymer film, the filler is preferably an inorganic filler.

As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent of the polymer film, the heat resistance, and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and pulverizing the liquid crystal polymer with a pulverizer or the like to obtain powdery liquid crystal. The liquid crystal polymer particles are preferably smaller than the thickness of each layer.

From the viewpoint of dielectric loss tangent, heat resistance, and step followability of the polymer film, the average particle diameter of the organic filler is preferably 5 nm to 20 μm and more preferably 100 nm to 10 μm.

As the inorganic filler, a known inorganic filler can be used.

Examples of a material of the inorganic filler include BN, Al₂O₃, AlN, TiO₂, SiO₂, barium titanate, strontium titanate, aluminum hydroxide, calcium carbonate, and a material containing two or more of these.

Among these, the inorganic filler is preferably at least one selected from the group consisting of silica, aluminum hydroxide, and boron nitride.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of dielectric loss tangent, heat resistance, and step followability of the polymer film, the average particle diameter of the inorganic filler is preferably 5 nm to 20 μm, more preferably 10 nm to 10 μm, still more preferably 20 nm to 1 μm, and particularly preferably 25 nm to 500 nm.

The polymer film may contain only one or two or more kinds of the fillers.

In a case where the polymer film contains a filler, from the viewpoint of dielectric loss tangent, heat resistance, and step followability of the polymer film, the content of the filler is preferably 3% by mass to 25% by mass, more preferably 5% by mass to 23% by mass, and still more preferably 10% by mass to 20% by mass with respect to the total mass of the polymer film.

### —Thermally Decomposable Impurities—

The polymer film of the present disclosure may contain a material (thermally decomposable impurities) that promotes the thermal decomposition of the constituent material, but the content thereof with respect to the total mass of the polymer film is preferably 500 ppm by mass or less and more preferably 100 ppm by mass or less.

Examples of the thermally decomposable impurities include metals such as copper, iron, nickel, titanium, cobalt, manganese, and vanadium, and chlorine.

### —Other Additives—

The polymer film may contain an additive other than the above-described components.

Known additives can be used as other additives. Specific examples thereof include a leveling agent, an antifoaming agent, an ultraviolet absorber, a flame retardant, and a colorant.

From the viewpoint of suppressing a decrease in heat resistance, it is preferable that the polymer film does not contain a metal atom, or the content of the metal atoms is less than 0.1% by mass with respect to the total amount of the polymer film. In a case of producing a polymer, a metal atom derived from the polymerization catalyst may remain. However, in a case of producing a polymer, for example, the content of metal atoms in the polymer can be reduced by producing the polymer using equipment in which metal atoms are less likely to be mixed, washing the produced polymer with hydrochloric acid, sulfuric acid, nitric acid, hydrofluoric acid, or the like, and performing post-treatment by a method such as filtering using a filter or an adsorbent, or melt extraction. In addition, the content of the metal atoms in the polymer film can also be reduced by mixing the polymer film with an additive having a low content of metal atoms or another polymer to produce the polymer film.

Examples of the metal atom include potassium, magnesium, nickel, palladium, antimony, aluminum, lithium, titanium, copper, sodium, iron, chromium, calcium, and molybdenum.

In the present disclosure, the content of the metal atoms in the polymer film is quantified using an ICP mass spectrometer (NexION 2000, manufactured by PerkinElmer Inc.).

### [Laminate]

The laminate according to the present disclosure is a laminate including a layer A, and a layer B on at least one surface of the layer A, in which the layer B has an elastic modulus at 160° C. of 10 MPa or less, and the laminate has a thermal mass loss rate at 290° C. of 1.0% by mass or less and a dielectric loss tangent of 0.01 or less.

The thermal mass loss rate of the laminate at 290° C. is preferably 0.8% by mass or less, more preferably 0.5% by mass or less, still more preferably 0.3% by mass or less, particularly preferably 0.2% by mass or less, and may be 0% by mass.

In the present disclosure, the thermal mass loss rate at 290° C. is measured by the following method.

The laminate is heated from 25° C. to 290° C. (temperature rising rate: 50° C./min) in a nitrogen environment and held for 40 minutes.

The mass of the laminate after 35 minutes from the start of the holding and the mass of the laminate after 25 minutes from the start of the holding are substituted into the following expression to obtain the thermal mass loss rate.

Thermal mass loss rate (%)=(mass of laminate 25 minutes after start of holding−mass of laminate 35 minutes after start of holding)/mass of laminate 25 minutes after start of holding×100

The dielectric loss tangent of the laminate is preferably 0.005 or less and more preferably more than 0 and 0.003 or less.

From the viewpoint of suppressing a decrease in heat resistance, it is preferable that the laminate does not contain a metal atom, or the content of the metal atoms is less than 0.1% by mass with respect to the total amount of the laminate. Specific examples of the metal atom are as described above.

In a case where the laminate includes only the layer A and the layer B, the total amount of the laminate means the content of the metal atoms with respect to the total amount of the layer A and the layer B. In addition, in a case where the laminate includes the layer A, the layer B, and another layer (for example, a layer C described later), the total amount of the laminate means the content of the metal atoms with respect to the total amount of the layer A, the layer B, and the other layer.

In the present disclosure, the content of the metal atoms in the laminate is quantified using an ICP mass spectrometer (NexION 2000, manufactured by PerkinElmer Inc.).

### —Layer A—

The layer A can contain a polymer. The polymer is as described in the polymer film, and the description of the preferred kind, content, and the like thereof will be omitted here.

The layer A may contain a thermoplastic resin containing a constitutional unit derived from a monomer having an aromatic hydrocarbon group, an antioxidant, a curing agent, a cured product of the thermoplastic resin and the curing agent, a filler, other additives, and the like. These are as described in the polymer film, and the description thereof will be omitted here.

The average thickness of the layer A is not particularly limited, but from the viewpoint of dielectric loss tangent, heat resistance, and step followability, it is preferably 5 μm to 90 μm, more preferably 10 μm to 70 μm, and particularly preferably 15 μm to 50 μm.

From the viewpoint of step followability, the elastic modulus of the layer A at 160° C. is preferably 50 MPa to 2000 MPa, more preferably 70 MPa to 1500 MPa, and still more preferably 150 MPa to 950 MPa.

In the present disclosure, the elastic modulus of the layer A at 160° C. is measured by the following method.

A polymer film or a laminate is cut in a thickness direction with a microtome to produce a cross-sectional evaluation sample (length: 2 mm, width: 2 mm), and an indentation elastic modulus at 160° C. is measured using a microhardness meter (product name “DUH-W201”, manufactured by Shimadzu Corporation) equipped with a Vickers indenter, using a nanoindentation method.

In a case where the layer A is thin and it is difficult to apply the nanoindentation method, the measurement is performed using a sample obtained by scraping off an unnecessary layer with a razor or removing a metal layer using a known wet etching method with an aqueous solution of ferric chloride or the like, followed by washing with pure water and drying the sample.

### —Layer B—

The layer B can contain a polymer. The polymer is as described in the polymer film, and the description of the preferred kind, content, and the like thereof will be omitted here.

The layer B may contain a thermoplastic resin containing a constitutional unit derived from a monomer having an aromatic hydrocarbon group, an antioxidant, a curing agent, a cured product of the thermoplastic resin and the curing agent, a filler, a thermally decomposable impurity, other additives, and the like. These are as described in the polymer film, and the description thereof will be omitted here.

Since the elastic modulus at 160° C., the elastic modulus at 260° C., the thermal mass loss rate at 290° C., the dielectric loss tangent, the average thickness, Tg, and the like of the layer B are the same as those of the polymer film, the description thereof will be omitted here.

In addition, the layer B preferably has the above-described phase-separated structure.

From the viewpoint of step followability and heat resistance, a ratio of an average thickness of the layer B to an average thickness of the laminate is preferably 0.2 or more, more preferably 0.3 or more, still more preferably 0.4 or more, and particularly preferably 0.5 or more.

### —Layer C—

The laminate according to the present disclosure has the layer C, and may have the layer B, the layer A, and the layer C in this order.

The layer C is preferably an adhesive layer. In addition, the layer C is preferably a surface layer (outermost layer).

The layer C can contain a polymer. The polymer is as described in the polymer film, and the preferred type thereof will not be described here.

From the viewpoint of adhesiveness, the content of the polymer with respect to the total mass of the layer C is preferably 50% by mass to 100% by mass, more preferably 60% by mass to 99.8% by mass, and still more preferably 70% by mass to 99.7% by mass.

The layer C may contain a thermoplastic resin containing a constitutional unit derived from a monomer having an aromatic hydrocarbon group, a curing agent, a cured product of the thermoplastic resin and the curing agent, a filler, other additives, and the like. These are as described in the polymer film, and the description thereof will be omitted here.

The average thickness of the layer C is not particularly limited, but from the viewpoint of dielectric loss tangent, heat resistance, and step followability, it is preferably 0.1 μm to 10 μm, more preferably 0.5 μm to 8 μm, and particularly preferably 1 μm to 5 μm.

### [Production Method of Laminate]

The production method of a laminate according to the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the laminate is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichloroethane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in the production method of the polymer film according to the present disclosure, in a case where the polymer film is produced by the co-casting method, the multilayer coating method, the co-extrusion method, or the like, a support may be used.

Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

The average thickness of the resin film support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### (Stretching)

In the laminate according to the present disclosure, stretching can be combined as appropriate from the viewpoint of controlling molecular alignment and adjusting thermal expansion coefficiency and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### [Use Application]

The polymer film and the laminate according to the present disclosure can be used for various applications. Among the various applications, the polymer film can be used suitably as a film for an electronic component such as a printed wiring board and more suitably for a flexible printed circuit board.

In addition, the polymer film and the laminate according to the present disclosure can be suitably used as a liquid crystal polymer film and a laminate for metal adhesion.

[Laminate with Metal]

The laminate with a metal according to the present disclosure includes the polymer film according to the present disclosure or the laminate according to the present disclosure, and a metal layer or a metal wire disposed on at least one surface of the polymer film or the laminate.

The metal layer or the metal wire may be made of a material known in the related art, and is preferably made of silver or copper and more preferably made of copper.

The metal layer or the metal wire may be disposed on both surfaces of the polymer film or the laminate. In this case, the two metal layers or metal wires may be metal layers or metal wires having the same material, thickness, and shape, or may be metal layers or metal wires having different materials, thicknesses, and shapes. From the viewpoint of adjusting the characteristic impedance, the two metal layers or metal wires may be metal layers or metal wires having different materials and thicknesses.

In one embodiment, the metal layer is a rolled metal foil formed by a rolling method or an electrolytic metal foil formed by an electrolytic method.

The peel strength of the polymer film or the laminate and the metal layer or the metal wire at 260° C. is preferably 1.0 kN/m or more, more preferably 1.3 kN/m to 10 kN/m, and still more preferably 1.5 kN/m to 8 kN/m.

In the present disclosure, the peel strength between the polymer film or the laminate and the metal layer or the metal wire at 290° C. is measured by the following method.

A peeling test piece having a width of 1.0 cm is prepared from a laminate (laminate with metal) of a polymer film or a laminate and a metal layer or a metal wire, the peeling test piece is fixed to a flat plate with a double-sided adhesive tape, and a strength (kN/m) in a case where the peeling test piece is peeled off at a rate of 50 mm/min according to the 180° method in conformity with JIS C 5016 (1994) is measured.

In a case where the thermal mass loss rate of the laminate with a metal at 290° C. is denoted by W1, and a peel strength of the polymer film or the laminate included in the laminate with a metal and the metal layer or the metal wire at 290° C. is denoted by F1, from the viewpoint of the step followability and the heat resistance, it is preferable that Expression (1) is satisfied.

$$F 1 \geq W 1 \times 2 8.5 + 0.4 \qquad Expression ( 1 )$$

In Expression (1), a unit of W1 is kN/m, and a unit of F1 is %.

The average thickness of the metal layer is not particularly limited, but is preferably 2 μm to 20 μm, more preferably 3 μm to 18 μm, and still more preferably 5 μm to 12 μm.

In a case where the metal layer is a copper foil, the copper foil may be a copper foil with a carrier that is formed on a support (carrier) in a peelable manner.

As the carrier, a known carrier can be used. An average thickness of the carrier is not particularly limited, but is preferably 10 μm to 100 μm and more preferably 18 μm to 50 μm.

From the viewpoint of suppressing distortion of the metal wire in a case of being bonded to the metal wire, the average thickness of the layer B is preferably larger than the average thickness of the metal.

The metal layer may be a metal layer having a circuit pattern. It is also preferable that the metal layer is processed into a desired circuit pattern by, for example, etching, and a flexible printed circuit board is formed. The etching method is not particularly limited, and a known etching method can be used.

[Production Method of Laminate with Metal]

The laminate with a metal according to the present disclosure can be produced by using a metal layer or a metal wire as a support in the production method of the laminate according to the present disclosure.

A metal layer or a metal wire may be provided on a surface of the laminate opposite to the side on which the support is provided, by heat sealing or the like.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

The details of the polymer and the additive (components other than the polymer) used for forming each layer of the laminate, and the copper foil are as follows.

### <Polymer or Elastomer>

Aromatic polyester amide P1 synthesized according to the following synthesis method (in Table 1, referred to as “P1”)
P2: Polyimide, PIAD-100H, manufactured by Arakawa Chemical Industries, Ltd., thermoplastic polyimide varnish

### —Synthesis of Aromatic Polyester Amide P1—

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and cooled to the room temperature. The obtained solid was pulverized by a pulverizer to obtain a powdered aromatic polyester amide A1a. A flow start temperature of the aromatic polyester amide A1a was 193° C. In addition, the aromatic polyester amide A1a was a fully aromatic polyester amide.

The aromatic polyester amide A1a was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide A1b. A flow start temperature of the aromatic polyester amide A1b was 220° C.

Aromatic polyester amide A1b is subjected to solid phase polymerization by increasing the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide P1 was measured using a differential scanning calorimetry apparatus, and the result was 311° C. The dielectric loss tangent of the aromatic polyester amide P1 was 0.005.

### <Additive>

F-1: Liquid crystal polymer particles prepared by production method described below

### —Preparation of F-1 (LCP Particles)—

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added. A temperature increases from a room temperature to 150° C. over 15 minutes while stirring under a nitrogen gas flow, and refluxing is performed at 150° C. for two hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid phase polymerization at 295° C. for one hour. After the solid phase polymerization, the mixture was cooled to room temperature over 5 hours.

The obtained liquid crystal polyester was pulverized using a jet mill (“KJ-200” manufactured by KURIMOTO LTD.) to obtain F-1 (LCP particles). F-1 (LCP particles) had a median diameter (D50) of 7 μm, a dielectric loss tangent of 0.0007, and a melting point of 334° C.
F-2: Hydrogenated styrene-ethylene-butylene-styrene block copolymer (SEBS), product name “TUFTEC M1913”, manufactured by Asahi Kasei Corporation, elastomer (weight-average molecular weight: 150,000)
F-3: Isobutylene-styrene block copolymer, manufactured by Kaneka Corporation, elastomer.
S-1: Hindered phenol-based antioxidant (radical scavenger), manufactured by SONGWON Industrial Co., Ltd., SONGNOX 3114
S-2: Semi-hindered phenol-based antioxidant (radical scavenger), manufactured by SONGWON Industrial Co., Ltd., SONGNOX 1010.
S-3: Hindered amine-based antioxidant (radical scavenger), manufactured by Sumitomo Chemical Co., Ltd., SUMILIZER GM
C-1: Curing agent, jER YX8800, manufactured by Mitsubishi Chemical Corporation
A-1: Silica particles, SC2050-MB, manufactured by Admatechs Co., Ltd.

### <Copper Foil>

Copper foil M1 (in Table 1, referred to as “M1”): CF-T9DA-SV-18, manufactured by Fukuda Metal Foil & Powder Co., Ltd., average thickness: 18 μm
Copper foil M2 (in Table 1, referred to as “M2”): MT18FL, manufactured by Mitsui Mining & Smelting Co., Ltd., average thickness: 1.5 μm
Copper foil M3 (hereinafter, referred to as “M3” in Table 1): CF-T49A-DS-18, manufactured by Fukuda Metal Foil & Powder Co., Ltd., average thickness: 18 μm

### Examples 1 to 11 and Comparative Examples 1 and 2

Solutions used for forming the layer A to the layer C were prepared according to the following method.

### —Preparation of Solution for Layer A—

The solution of the polymer and the additives shown in Table 1 were mixed so as to have the mass ratios shown in Table 1, and N-methylpyrrolidone was added thereto so that the concentration of solid contents was 25% by mass, thereby obtaining a solution for a layer A.

### —Preparation of Solution for Layer B—

The solution of the polymer and the additives shown in Table 1 were mixed so as to have the mass ratios shown in Table 1, and N-methylpyrrolidone was added thereto so that the concentration of solid contents was 20% by mass, thereby obtaining a solution for a layer B.

### —Preparation of Solution for Layer C—

8 parts by mass of aromatic polyester amide P1 was added to 92 parts by mass of N-methylpyrrolidone, and the mixture was stirred at 140° C. for 4 hours in a nitrogen atmosphere to obtain a solution of aromatic polyester amide P1 (concentration of solid contents: 8% by mass).

0.04 parts by mass of an aminophenol-type epoxy resin (product name “jER630”, manufactured by Mitsubishi Chemical Corporation) was mixed with 9.96 parts by mass of the solution of the aromatic polyester amide P1 to prepare a solution for a layer C.

### —Preparation of Single-Sided Copper-Clad Laminated Plate—

The obtained solutions for the layer C, the layer B, and the layer A were fed to a slot die coater equipped with a slide coater, and applied to the treated surface of the copper foil (first metal layer) shown in Table 1 in a three-layer configuration (layer C/layer A/layer B) by adjusting the flow rate so that the average thickness after drying was 3 μm for the layer C and the average thicknesses of the layer A and the layer B were as shown in Table 1. The solvent was removed from the coating film by drying at 40° C. for 4 hours. Further, a heat treatment was performed in a nitrogen atmosphere by raising the temperature from room temperature to 300° C. at 1° C./min and holding the temperature for 2 hours, thereby obtaining a laminate (single-sided copper-clad laminated plate) having a metal layer (copper layer).

The layer C, the layer B, and the layer A of the obtained film were scraped off with a ceramic cutter, and the content of the metal atoms was quantified using an ICP mass spectrometer (NexION 2000, manufactured by PerkinElmer Inc.), and the total content of the potassium atom and the magnesium atom was 0.01% by mass.

### —Preparation of Double-Sided Copper-Clad Laminated Plate—

The copper foil and the one-single-sided copper-clad laminated plate were laminated in this order such that the treated surface of the copper foil (the second metal layer) shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a heat sealer (product name “MP-SNL”, manufactured by Toyo Seiki Seisaku-sho, Ltd.), the obtained double-sided copper-clad laminated plate precursor was heat-sealed for 60 minutes under conditions of 300° C. and 4 MPa to prepare a double-sided copper-clad laminated plate.

The obtained double-sided copper-clad laminated plate of Examples was cut with a microtome to produce a cross-sectional observation sample, and the layer B was observed with an optical microscope, and it was confirmed that the polymer and the additive 1 formed a phase-separated structure.

TABLE 1

| | Layer B | | | | | | | | | | | | | | | |
|---|---|---|---|---|---|---|---|---|---|---|---|---|---|---|---|---|
| | | | | | | | | | | Average | | | | | | |
| | | | | | | | | | | thick- | | | | | | |
| | | | | | | | | | | ness | | | | | | |
| | | | | | | | | | | of | | | | | | |
| | | | | | | | | | | Layer | Layer A | | | | | |
| | Polymer | | Additive 1 | | Additive 2 | | Additive 3 | | Aver- | B/ | Polymer | | Additive 1 | | Aver- | |
| | | Content | | Content | | Content | | Content | age | average | | Content | | Content | age | |
| | | [parts | | [parts | | [parts | | [parts | thick- | thick- | | [parts | | [parts | thick- | |
| | | by | | by | | by | | by | ness | ness of | | by | | by | ness | Copper |
| | Kind | mass] | Kind | mass] | Kind | mass] | Kind | mass] | [μm] | laminate | Kind | mass] | Kind | mass] | [μm] | foil |
| Ex- | P1 | 20 | F-2 | 80 | S-1 | 0.05 | — | — | 30 | 0.55 | P1 | 25 | F-1 | 75 | 22 | M1 |
| ample 1 | | | | | | | | | | | | | | | | |
| Ex- | P1 | 20 | F-2 | 80 | S-1 | 0.05 | — | — | 15 | 0.3 | P1 | 25 | F-1 | 75 | 32 | M1 |
| ample 2 | | | | | | | | | | | | | | | | |
| Ex- | P1 | 20 | F-2 | 80 | S-1 | 0.1 | — | — | 25 | 0.5 | P1 | 25 | F-1 | 75 | 22 | M1 |
| ample 3 | | | | | | | | | | | | | | | | |
| Ex- | P1 | 20 | F-2 | 80 | S-1 | 0.1 | — | — | 25 | 0.5 | P1 | 25 | F-1 | 75 | 22 | M1 |
| ample 4 | | | | | | | | | | | | | | | | |
| Ex- | P1 | 20 | F-2 | 80 | S-1 | 5 | — | — | 25 | 0.5 | P1 | 25 | F-1 | 75 | 22 | M1 |
| ample 5 | | | | | | | | | | | | | | | | |
| Ex- | P1 | 20 | F-2 | 80 | S-2 | 0.1 | — | — | 25 | 0.5 | P1 | 25 | F-1 | 75 | 22 | M1 |
| ample 6 | | | | | | | | | | | | | | | | |
| Ex- | P1 | 20 | F-2 | 80 | S-3 | 0.1 | — | — | 25 | 0.5 | P1 | 25 | F-1 | 75 | 22 | M1 |
| ample 7 | | | | | | | | | | | | | | | | |
| Ex- | P1 | 20 | F-3 | 80 | S-1 | 0.1 | — | — | 25 | 0.5 | P1 | 25 | F-1 | 75 | 22 | M1 |
| ample 8 | | | | | | | | | | | | | | | | |
| Ex- | P1 | 20 | F-3 | 80 | — | — | — | — | 25 | 0.5 | P1 | 25 | F-1 | 75 | 22 | M1 |
| ample 9 | | | | | | | | | | | | | | | | |
| Ex- | P1 | 40 | F-2 | 60 | S-1 | 0.1 | — | — | 30 | 0.6 | P1 | 25 | F-1 | 75 | 17 | M1 |
| ample 10 | | | | | | | | | | | | | | | | |
| Ex- | P1 | 40 | F-2 | 80 | S-1 | 0.1 | — | — | 25 | 0.5 | P1 | 25 | F-1 | 75 | 22 | M3 |
| ample 11 | | | | | | | | | | | | | | | | |
| Com- | — | — | F-2 | 64 | C-1 | 4 | A-1 | 32 | 25 | 0.5 | P2 | 100 | — | — | 35 | M1 |
| parative | | | | | | | | | | | | | | | | |
| Ex- | | | | | | | | | | | | | | | | |
| ample 1 | | | | | | | | | | | | | | | | |
| Com- | P1 | 100 | F-2 | — | — | — | — | — | 25 | 0.5 | P1 | 25 | F-1 | 75 | 22 | M1 |
| parative | | | | | | | | | | | | | | | | |
| Ex- | | | | | | | | | | | | | | | | |
| ample 2 | | | | | | | | | | | | | | | | |

### <<Measurement of Dielectric Loss Tangent>>

The first metal layer and the second metal layer were etched from the double-sided copper-clad laminated plate.

The dielectric loss tangent of the taken-out laminate was measured by the following method. The results are shown in Table 1.

A dielectric constant was measured by a resonance perturbation method at a frequency of 10 GHz.

A 10 GHz cavity resonator (CP531 manufactured by KANTO Electronic Application and Development Inc.) is connected to a network analyzer (“E8363B” manufactured by Agilent Technology Co., Ltd.), the laminate is inserted into the cavity resonator, and the dielectric loss tangent of the laminate is measured from change in resonance frequency before and after insertion for 96 hours under an environment of a temperature of 25° C. and humidity of 60% RH. The results are shown in Table 2.

### <<Measurement of Elastic Modulus of Layer B at 160° C. And 290° C.>>

The copper foil on the layer B side of the double-sided copper-clad laminated plate was removed with an aqueous solution of ferric chloride, and then dried after being washed with pure water. A film cross-section sample (length: 2 mm× width: 2 mm) produced by cutting the surface of the layer B with a microtome was prepared.

Next, an elastic modulus at 160° C. and an elastic modulus at 290° C. were measured as indentation elastic moduli using a nanoindentation method. The indentation elastic modulus was measured by using a microhardness meter (product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec. The results are shown in Table 2.

### <<Measurement of Thermal Mass Loss Rate>>

The first metal layer and the second metal layer were etched from the double-sided copper-clad laminated plate.

By the following method, the extracted laminate was heated from 25° C. to 290° C. (temperature rising rate: 50° C./min) in a nitrogen environment and held for 40 minutes.

The mass of the laminate after 35 minutes from the start of the holding and the mass of the laminate after 25 minutes from the start of the holding were substituted into the following expression to obtain the thermal mass loss rate. The results are shown in Table 2.

Thermal mass loss rate (%)=(mass of laminate 25 minutes after start of holding−mass of laminate 35 minutes after start of holding)/mass of laminate 25 minutes after start of holding×100

### <<Evaluation of Step Followability>>

—Preparation of Substrate a with Wiring Patterns—

The copper foil M1 was patterned by a known photofabrication method to prepare a wiring substrate including three pairs of signal lines. A length of the signal line was 100 mm, and a width of the signal line was set such that characteristic impedance was 50Ω.

### —Lamination Step—

Using the above-described wiring substrate and the above-described pair of single-sided copper-clad laminated plates, the single-sided copper-clad laminated plate, the wiring substrate, and the single-sided copper-clad laminated plate were laminated in this order such that the layer B side of the single-sided copper-clad laminated plate was in contact with the wiring substrate.

Using a vacuum press device, the metal wires were laminated at a press temperature of 160° C. to prepare a flexible wiring board.

The flexible printed circuit was cut with a microtome, the cross section was observed with an optical microscope, and the evaluation was performed based on the following evaluation standards. The results are shown in Table 2.

### (Evaluation Standard)

A: No distortion was recognized in the signal line and the ground line.
B: While no distortion was recognized in the signal lines, distortion was recognized in the ground line.
C: Distortion was recognized in a pair of signal lines.
D: Distortion was recognized in two pairs or three pairs of signal lines.

### <<Evaluation of Heat Resistance>>

The double-sided copper-clad laminated plates prepared in Examples and Comparative Examples were cut out to have a size of 30 mm×30 mm and used as samples. The sample was immersed in the hot solder at 288° C. for 10 seconds. The sample after the three-time heating was cut with a razor, and the cross section was observed with an optical microscope, and the heat resistance was evaluated based on the following evaluation standards. The results are shown in Table 2.

### (Evaluation Standard)

A: No peeling was recognized between the layer B and the second metal layer.
B: Peeling was recognized between the layer B and the second metal layer with a width of 1 mm or less.
C: Peeling was recognized between the layer B and the second metal layer with a width of more than 1 mm.

### <<Measurement of Peel Strength of Double-Sided Copper-Clad Laminated Plate>>

A peeling test piece having a width of 1.0 cm was prepared from each of the double-sided copper-clad laminated plates produced in Examples and Comparative Examples, the double-sided copper-clad laminated plate was fixed to a flat plate with a double-sided adhesive tape, and the second metal layer was peeled off from the double-sided copper-clad laminated plate at a rate of 50 mm/min in an environment of 260° C. according to the 180° method in accordance with JIS C 5016 (1994), and the peel strength (kN/m) between the layer B and the second metal layer was measured. The results are shown in Table 2.

TABLE 2

| | Dielectric | Elastic modulus of | | Thermal mass | Evaluation | Evaluation | Peel strength |
|---|---|---|---|---|---|---|---|
| | loss | latyer B [MPa] | | loss rate | of step | of heat | at 260° C. |
| | tangent | 160° C. | 260° C. | [% by mass] | followability | resistance | [kN/m] |
| Example 1 | 0.002 | 0.4 | 0.04 | 0.2 | A | B | 2 |
| Example 2 | 0.002 | 0.4 | 0.04 | 0.1 | B | A | 2 |
| Example 3 | 0.002 | 0.4 | 0.04 | 0.1 | A | A | 2 |
| Example 4 | 0.002 | 0.4 | 0.04 | 0.1 | A | A | 3 |
| Example 5 | 0.005 | 0.3 | 0.03 | 0.6 | A | B | 2 |
| Example 6 | 0.002 | 0.4 | 0.04 | 0.1 | A | A | 2 |
| Example 7 | 0.002 | 0.4 | 0.04 | 0.1 | A | A | 2 |
| Example 8 | 0.002 | 0.4 | 0.04 | 0.1 | A | A | 2 |
| Example 9 | 0.002 | 0.4 | 0.04 | 0.4 | A | B | 2 |
| Example 10 | 0.002 | 1.0 | 0.12 | 0.1 | B | A | 3 |
| Example 11 | 0.002 | 0.4 | 0.04 | 0.1 | A | A | 4 |
| Comparative | 0.01 | 0.4 | 0.04 | 1.3 | A | C | 2 |
| Example 1 | | | | | | | |
| Comparative | 0.003 | 16 | 0.04 | 0.0 | C | A | 10 |
| Example 2 | | | | | | | |

From the results shown in Table 2, it can be seen that the laminates of Examples 1 to 11, which are the laminates according to the present disclosure, have excellent step followability and excellent heat resistance as compared with the laminates of Comparative Examples 1 and 2.

The disclosure of Japanese Patent Application No. 2022-197497 filed on Dec. 9, 2022 is incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer film,
wherein the polymer film has
an elastic modulus at 160° C. of 10 MPa or less,
a thermal mass loss rate at 290° C. of 1.0% by mass or less, and
a dielectric loss tangent of 0.01 or less.

2. The polymer film according to claim 1,
wherein the polymer film has an elastic modulus at 290° C. is 0.01 MPa or more.

3. The polymer film according to claim 1, further comprising:
an antioxidant.

4. The polymer film according to claim 3,
wherein the antioxidant is a radical scavenger.

5. The polymer film according to claim 1,
wherein the polymer film does not contain a metal atom, or a content of a metal atom is less than 0.1% by mass with respect to a total amount of the polymer film.

6. The polymer film according to claim 1, further comprising:
a polymer,
wherein the polymer contains a liquid crystal polymer.

7. The polymer film according to claim 6,
wherein the polymer contains an aromatic polyester amide.

8. The polymer film according to claim 1, further comprising:
a thermoplastic resin containing a constitutional unit based on a monomer having an aromatic hydrocarbon group.

9. A laminate comprising:
a layer A; and
a layer B provided on at least one surface of the layer A,
wherein the layer B has an elastic modulus at 160° C. of 10 MPa or less, and
the laminate has a thermal mass loss rate at 290° C. of 1.0% by mass or less and a dielectric loss tangent of 0.01 or less.

10. The laminate according to claim 9,
wherein a ratio of an average thickness of the layer B to an average thickness of the laminate is 0.3 or more.

11. The laminate according to claim 9,
wherein the laminate has an elastic modulus at 290° C. of 0.01 MPa or more.

12. The laminate according to claim 9, further comprising:
an antioxidant.

13. The laminate according to claim 12,
wherein the antioxidant is a radical scavenger.

14. The laminate according to claim 9, further comprising:
a layer C,
wherein the layer B, the layer A, and the layer C are provided in this order.

15. The laminate according to claim 9,
wherein the laminate does not contain a metal atom, or a content of a metal atom is less than 0.1% by mass with respect to a total amount of the laminate.

16. A laminate with a metal comprising:
the polymer film according to claim 1; and
a metal layer or a metal wire disposed on at least one surface of the polymer film.

17. A laminate with a metal comprising:
the laminate according to claim 9; and
a metal layer or a metal wire disposed on at least one surface of the laminate.
